(19) United States
(12) Patent Application Publication
(10) Pub. No.: US 2026/0189211 A1
(43) Pub. Date: Jul. 2, 2026

(54) ACOUSTIC WAVE DEVICE

(71) Applicant: Murata Manufacturing Co., Ltd., Nagaokakyo-shi, Kyoto-fu (JP)

(72) Inventors: Katsuya DAIMON, Nagaokakyo-shi (JP); Akihiro IYAMA, Nagaokakyo-shi (JP)

(21) Appl. No.: 18/769,834

(22) PCT Filed: Jan. 12, 2023
(86) PCT No.: PCT/JP2023/000612

§ 371 Date: Jul. 11, 2024

(30) Foreign Application Priority Data
Jan. 14, 2022 (JP) 63299575

(51) Int. Cl. H03H 9/02; H03H 9/13; H03H 9/56

(52) U.S. Cl. CPC H03H 9/02228; H03H 9/02015; H03H 9/02157; H03H 9/132; H03H 9/568

(57) ABSTRACT

An acoustic wave device includes a piezoelectric substrate including a support and a piezoelectric layer made of lithium tantalate or lithium niobate, a functional electrode on the piezoelectric layer and including a pair of electrode fingers, and a dielectric film on the piezoelectric layer and covering the pair of electrode fingers. An acoustic reflection portion overlaps the functional electrode in plan view. In a case where a thickness of the piezoelectric layer is d and a center-to-center distance between the electrode fingers adjacent to each other is p, d/p is about 0.5 or less. The electrode fingers include first and second surfaces facing each other, and a side surface connected to the first and second surfaces. The second surface is located on a side of the piezoelectric layer.

### CROSS REFERENCE TO RELATED APPLICATIONS

This application claims the benefit of priority to Provisional Application No. 63/299,575 filed on Jan. 14, 2022 and is a Continuation Application of PCT Application No. PCT/JP 2023/000612 filed on Jan. 12, 2023. The entire contents of each application are hereby incorporated herein by reference.

### BACKGROUND OF THE INVENTION

### 1. Field of the invention

The present invention relates to acoustic wave devices.

### 2. Description of the Related Art

In the related art, an acoustic wave device has been widely used for a filter or the like of a mobile phone. In recent years, as described in U.S. Pat. No. 10,491,192 below, an acoustic wave device using a bulk wave in a thickness shear mode has been proposed. In the acoustic wave device, a piezoelectric layer is provided on a support. A pair of electrodes are provided on the piezoelectric layer. The pair of electrodes face each other on the piezoelectric layer and are connected to different potentials. By applying an alternating-current (AC) voltage between the electrodes, the bulk wave in the thickness shear mode is excited.

In the acoustic wave device described in U.S. Pat. No. 10,491,192, for example, a protective film may be provided on the piezoelectric layer to cover the electrode for exciting an acoustic wave. The inventors of example embodiments of the present invention have discovered that, in a case where the protective film is provided as described above, an unnecessary wave caused by the protective film is generated. A frequency at which the unnecessary wave is generated is close to an anti-resonant frequency. Therefore, in a case where the acoustic wave device is used in a filter device, there is a concern that filter characteristics are deteriorated.

### SUMMARY OF THE INVENTION

Example embodiments of the present invention provide acoustic wave devices each able to keep a frequency at which an unnecessary wave is generated away from an anti-resonant frequency.

An example embodiment of the present invention provides an acoustic wave device including a piezoelectric substrate including a support that includes a support substrate, and a piezoelectric layer provided on the support and made of lithium tantalate or lithium niobate, a functional electrode provided on the piezoelectric layer and including at least one pair of electrode fingers, and a dielectric film provided on the piezoelectric layer and covering the at least one pair of electrode fingers. An acoustic reflection portion is provided at a position overlapping at least a portion of the functional electrode in plan view. Where a thickness of the piezoelectric layer is d and a center-to-center distance between the electrode fingers adjacent to each other is p, d/p is about 0.5 or less. The electrode finger includes a first surface and a second surface facing each other in a thickness direction, and a side surface connected to the first surface and the second surface. The second surface is located on a side of the piezoelectric layer. The dielectric film includes an electrode finger surface cover portion covering the first surface of the electrode finger, a side surface cover portion covering the side surface of the electrode finger, and a piezoelectric layer cover portion covering the piezoelectric layer. The electrode finger surface cover portion includes a center portion located at a center in a direction orthogonal or substantially orthogonal to a direction in which the electrode finger extends. Where a portion in which the side surface cover portion and the piezoelectric layer cover portion are connected to each other is a connection portion, and a minimum value of a thickness of the connection portion is tcm, tcm≥0. Where a thickness of the center portion of the electrode finger surface cover portion is te, te>tcm.

According to example embodiments of the present invention, it is possible to provide acoustic wave devices each able to keep the frequency at which the unnecessary wave is generated away from the anti-resonant frequency.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic cross-sectional view showing a vicinity of a first electrode finger along line II-II in FIG. 1.

FIG. 4 is a schematic cross-sectional view showing a portion of an acoustic wave device according to a comparative example, corresponding to the cross section taken along the line II-II in FIG. 1.

FIG. 5 is a view showing impedance frequency characteristics in the first example embodiment of the present invention and the comparative example.

FIG. 6 is a schematic cross-sectional view showing a vicinity of a first electrode finger according to a modified example of the first example embodiment of the present invention along an electrode finger facing direction.

FIG. 7 is a circuit diagram of a filter device according to a second example embodiment of the present invention.

FIG. 8A is a schematic perspective view showing an appearance of an acoustic wave device using a bulk wave in a thickness shear mode, and FIG. 8B is a plan view showing an electrode structure on a piezoelectric layer.

FIG. 9 is a cross-sectional view of a portion taken along line A-A in FIG. 8A.

FIG. 10A is a schematic elevational cross-sectional view showing a Lamb wave that propagates through a piezoelectric film of an acoustic wave device, and FIG. 10B is a schematic elevational cross-sectional view showing a bulk wave in a thickness shear mode that propagates through the piezoelectric film of the acoustic wave device.

FIG. 11 is a view showing an amplitude direction of a bulk wave in the thickness shear mode.

FIG. 12 is a view showing resonance characteristics of an acoustic wave device using a bulk wave in a thickness shear mode.

FIG. 13 is a view showing a relationship between d/p and a fractional bandwidth as a resonator in a case where a center-to-center distance of electrodes adjacent to each other is p and a thickness of a piezoelectric layer is d.

FIG. 14 is a plan view of an acoustic wave device using a bulk wave in a thickness shear mode.

FIG. 15 is a view showing resonance characteristics of an acoustic wave device of a reference example in which a spurious response appears.

FIG. 16 is a view showing a relationship between a fractional bandwidth and a phase rotation amount of an impedance of a spurious response standardized at about 180 degrees as a magnitude of the spurious response.

FIG. 17 is a view showing a relationship between d/2p and a metallization ratio MR.

FIG. 18 is a view showing a map of a fractional bandwidth with respect to Euler angles (0°, θ, ψ) of LiNbO₃ in a case where d/p is infinitely close to 0.

FIG. 19 is an elevational cross-sectional view of an acoustic wave device according to an example embodiment of the present invention including an acoustic multilayer film.

### DETAILED DESCRIPTION OF THE EXAMPLE EMBODIMENTS

Hereinafter, the present invention will be clarified by describing specific example embodiments of the present invention with reference to the accompanying drawings.

Each of example embodiments described in the present specification is merely an example, and partial replacement or combination of the configurations can be made between different example embodiments.

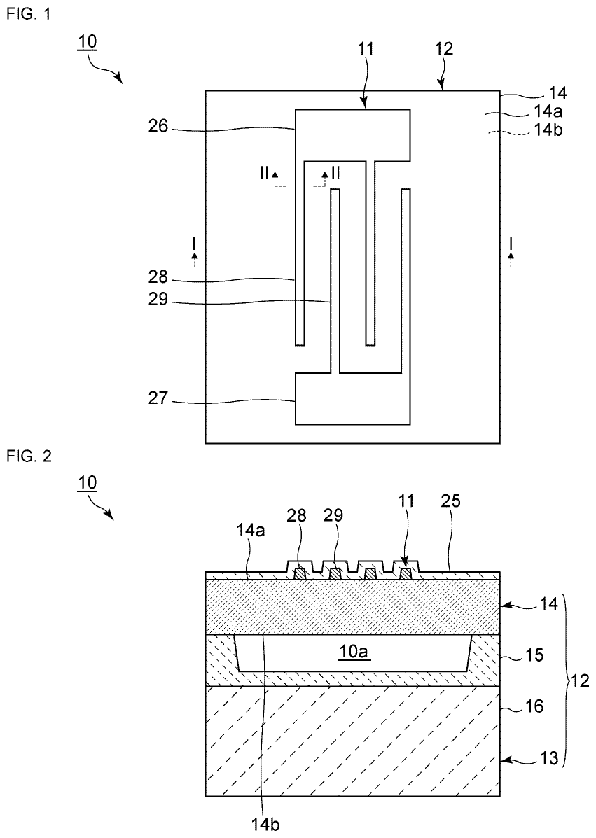

FIG. 1 is a schematic plan view of an acoustic wave device according to a first example embodiment of the present invention. FIG. 2 is a schematic cross-sectional view taken along line I-I in FIG. 1. In FIG. 1, a dielectric film to be described later is not shown.

As shown in FIG. 1, the acoustic wave device 10 includes a piezoelectric substrate 12 and an interdigital transducer (IDT) electrode 11. As shown in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may include only the support substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As a material of the support substrate 16, for example, a semiconductor such as silicon, a ceramic such as aluminum oxide, or the like can be used. As the material of the insulating layer 15, for example, an appropriate dielectric such as silicon oxide or tantalum oxide can be used. The piezoelectric layer 14 is, for example, a lithium niobate layer such as a LiNbO₃ layer or a lithium tantalate layer such as a LiTaO₃ layer.

As shown in FIG. 2, a recess portion is provided in the insulating layer 15. The piezoelectric layer 14 is provided on the insulating layer 15 to cover and close the recess portion. As a result, a hollow portion is provided. The hollow portion is a cavity portion 10a. In the present example embodiment, the support 13 and the piezoelectric layer 14 are disposed such that a portion of the support 13 and a portion of the piezoelectric layer 14 face each other with the cavity portion 10a interposed therebetween. However, the recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. The cavity portion 10a may be a through hole provided in the support 13.

The IDT electrode 11 as a functional electrode is provided on the first main surface 14a of the piezoelectric layer 14. The dielectric film 25 is provided on the first main surface 14a to cover the IDT electrode 11. As the material of the dielectric film 25, for example, silicon oxide, silicon nitride, silicon oxynitride, or the like can be used. However, the material of the dielectric film 25 is not limited to the above-described material.

In plan view, at least a portion of the IDT electrode 11 overlaps the cavity portion 10a of the piezoelectric substrate 12. In the present specification, “in plan view” means that the support 13 and the piezoelectric layer 14 are viewed along a laminating direction from a direction corresponding to an up direction in FIG. 2. In FIG. 2, for example, the piezoelectric layer 14 side is an upper side of the support substrate 16 and the piezoelectric layer 14.

As shown in FIG. 1, the IDT electrode 11 includes one pair of busbars and a plurality of electrode fingers. Specifically, the one pair of busbars includes a first busbar 26 and a second busbar 27. The first busbar 26 and the second busbar 27 face each other. The plurality of electrode fingers include a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated with each other. The IDT electrode 11 may include a single metal film or a laminated metal film.

The functional electrode according to example embodiments of the present invention need only include at least one pair of the first electrode finger 28 and the second electrode finger 29.

Hereinafter, the first electrode finger 28 and the second electrode finger 29 may be simply referred to as an electrode finger. In a case where a direction in which the plurality of electrode fingers extend is an electrode finger extending direction and a direction in which the electrode fingers adjacent to each other face each other is an electrode finger facing direction, in the present example embodiment, the electrode finger extending direction and the electrode finger facing direction are orthogonal or substantially orthogonal to each other.

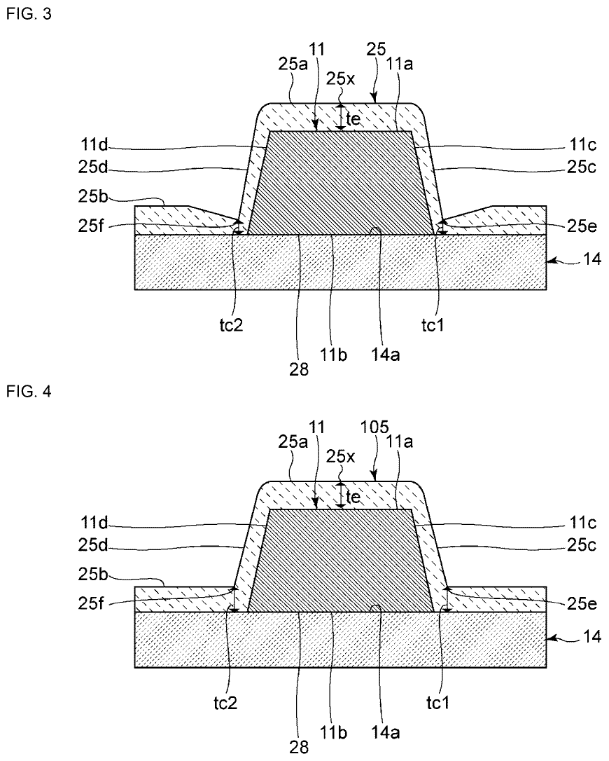

FIG. 3 is a schematic cross-sectional view showing the vicinity of the first electrode finger along line II-II in FIG. 1.

Each first electrode finger 28 includes a first surface 11a and a second surface 11b. The first surface 11a and the second surface 11b face each other in a thickness direction. The second surface 11b of the first surface 11a and the second surface 11b is located on the piezoelectric layer 14 side. Each first electrode finger 28 includes a side surface. The side surface is connected to the first surface 11a and the second surface 11b. More specifically, the side surface includes a first side surface portion 11c and a second side surface portion 11d. The first side surface portion 11c and the second side surface portion 11d face each other in a direction orthogonal or substantially orthogonal to the electrode finger extending direction. Similarly, each of the second electrode fingers 29 shown in FIG. 2 also includes a first surface 11a and a second surface 11b, and a first side surface portion 11c and a second side surface portion 11d.

The acoustic wave device 10 according to the present example embodiment is an acoustic wave resonator configured to use a bulk wave in a thickness shear mode. More specifically, in the acoustic wave device 10, in a case where a thickness of the piezoelectric layer 14 is d and a center-to-center distance of the electrode fingers adjacent to each other is p, d/p is, for example, about 0.5 or less. As a result, the bulk wave in the thickness shear mode is suitably excited. A region, which is a region in which the adjacent electrode fingers overlap each other when seen from the electrode finger facing direction and a region between the centers of the adjacent electrode fingers, is an excitation region. In each excitation region, the bulk wave of the thickness shear mode is excited.

The cavity portion 10a shown in FIG. 2 is an acoustic reflection portion according to the present example embodiment. The acoustic reflection portion can effectively confine the energy of an acoustic wave on the piezoelectric layer 14 side. As the acoustic reflection portion, an acoustic reflection film such as, for example, an acoustic multilayer film described later may be provided.

As described above, the dielectric film 25 covers the IDT electrode 11. As shown in FIG. 3, the dielectric film 25 includes an electrode finger surface cover portion 25a, a side surface cover portion, a piezoelectric layer cover portion 25b, and a connection portion. The electrode finger surface cover portion 25a is a portion that covers the first surface 11a of the electrode finger. The electrode finger surface cover portion 25a includes a center portion 25x. The center portion 25x is a portion located at the center of the electrode finger surface cover portion 25a in a direction orthogonal or substantially orthogonal to the electrode finger extending direction.

The side surface cover portion is a portion that covers the side surface of the electrode finger. More specifically, the side surface cover portion includes a first side surface cover portion 25c and a second side surface cover portion 25d. The first side surface cover portion 25c covers the first side surface portion 11c of the electrode finger. The second side surface cover portion 25d covers the second side surface portion 11d of the electrode finger. Therefore, the first side surface cover portion 25c and the second side surface cover portion 25d face each other in the direction orthogonal or substantially orthogonal to the electrode finger extending direction.

The piezoelectric layer cover portion 25b is a portion that covers the piezoelectric layer 14. The connection portion is a portion in which the side surface cover portion and the piezoelectric layer cover portion 25b are connected to each other. More specifically, the connection portion includes a first connection portion 25e and a second connection portion 25f. The first connection portion 25e is a portion in which the first side surface cover portion 25c and the piezoelectric layer cover portion 25b are connected to each other. The second connection portion 25f is a portion in which the second side surface cover portion 25d and the piezoelectric layer cover portion 25b are connected to each other.

In FIG. 3, a portion of the dielectric film 25 that covers the first electrode finger 28 and the vicinity of the portion is shown. However, the dielectric film 25 also includes the electrode finger surface cover portion 25a, the side surface cover portion, the piezoelectric layer cover portion 25b, and the connection portion in a portion of the dielectric film 25 that covers the second electrode finger 29 and in the vicinity thereof. In example embodiments of the present invention, a thickness of the connection portion may be zero. In the present example embodiment, in a case where the minimum value of the thickness of the connection portion is tcm, tcm≥0.

A feature of the present example embodiment is that, in the dielectric film 25, a thickness of at least a portion of the connection portion is smaller than a thickness of the center portion 25x of the electrode finger surface cover portion 25a. Specifically, in a case where the thickness of the center portion 25x is te, te>tcm. More specifically, in the present example embodiment, in a case where a thickness of the first connection portion 25e of the dielectric film 25 is tc1, a thickness of the second connection portion 25f is tc2, and the thickness of the center portion 25x is te, te>tc1 and te>tc2. As a result, a frequency at which the unnecessary wave is generated can be kept away from the anti-resonant frequency. This advantageous effect will be described below by comparing the present example embodiment will a comparative example.

In the comparative example, as shown in FIG. 4, a dielectric film 105 is different from that of the first example embodiment in that tc1=tc2=te. In the first example embodiment and the comparative example, the impedance frequency characteristics are compared.

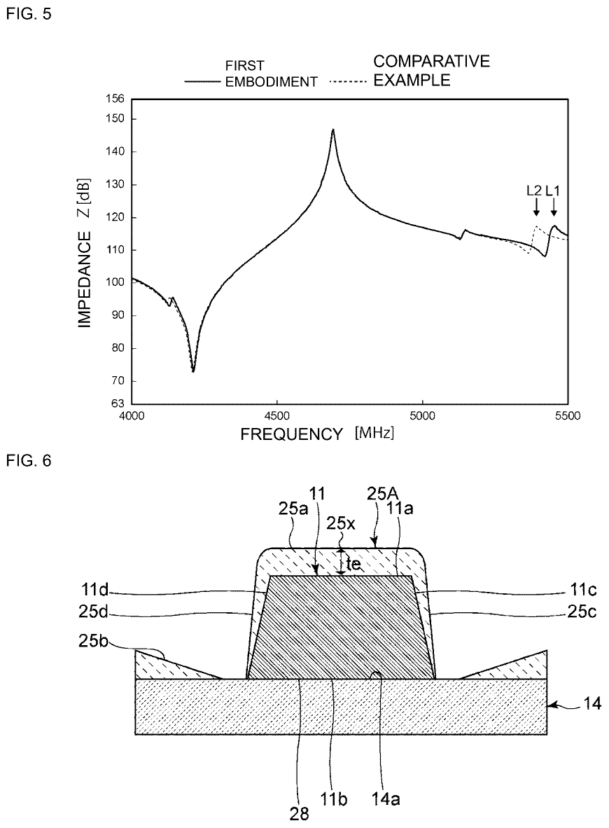

FIG. 5 is a view showing the impedance frequency characteristics in the first example embodiment and the comparative example. An arrow L1 in FIG. 5 indicates a frequency at which the unnecessary wave is generated in the first example embodiment, and an arrow L2 indicates a frequency at which the unnecessary wave is generated in the comparative example.

As shown by the arrow L1 and the arrow L2 in FIG. 5, in the first example embodiment, the frequency at which the unnecessary wave is generated can be kept farther away from the anti-resonant frequency than in than in the comparative example. Specifically, in the first example embodiment, the frequency at which the unnecessary wave is generated can be kept away from the anti-resonant frequency toward the high frequency side.

The first connection portion 25e of the dielectric film 25 shown in FIG. 3 extends in the electrode finger extending direction. The same applies to second connection portion 25f. In the present example embodiment, at least one of the thickness tc1 of at least a portion of the first connection portion 25e of the dielectric film 25 and the thickness tc2 of at least a portion of the second connection portion 25f of the dielectric film 25 may only be smaller than the thickness te of the center portion 25x. However, it is preferable that at least one of the thickness tc1 of the entire or substantially the entire first connection portion 25e of the dielectric film 25 and the thickness tc2 of the entire or substantially the entire second connection portion 25f of the dielectric film 25 is smaller than the thickness te of the center portion 25x. As a result, the frequency at which the unnecessary wave is generated can be effectively kept away from the anti-resonant frequency.

It is more preferable that both the thickness tc1 of the entire or substantially the entire first connection portion 25e of the dielectric film 25 and the thickness tc2 of the entire or substantially the entire second connection portion 25f are smaller than the thickness te of the center portion 25x. As a result, the frequency at which the unnecessary wave is generated can be kept farther away from the anti-resonant frequency. In a case where the thickness tc1 of the first connection portion 25e and the thickness tc2 of the second connection portion 25f are compared with the thickness te of the center portion 25x, the thicknesses may only be compared in the same cross section, for example, along the direction orthogonal or substantially orthogonal to the electrode finger extending direction.

The thickness of the connection portion in the dielectric film 25 may be zero. For example, in the modified example of the first example embodiment shown in FIG. 6, a thickness te1 of the first connection portion is zero, and a thickness te2 of the second connection portion is zero. In the present modified example as well, the dielectric film 25A includes the piezoelectric layer cover portion 25b. However, the piezoelectric layer 14 is exposed from the dielectric film 25A between the piezoelectric layer cover portion 25b and the first side surface cover portion 25c. Similarly, the piezoelectric layer 14 is exposed from the dielectric film 25A between the piezoelectric layer cover portion 25b and the second side surface cover portion 25d.

In the present modified example as well, te>tcm. Also, te>tc1 and te>tc2. As a result, as in the first example embodiment, the frequency at which the unnecessary wave is generated can be kept away from the anti-resonant frequency.

In the first example embodiment shown in FIG. 3 and the like, the dielectric film 25 is provided on the piezoelectric layer 14 to cover the entire or substantially the entire IDT electrode 11. However, the dielectric film 25 may only cover the plurality of electrode fingers.

In the acoustic wave device 1, the IDT electrode 11 and the dielectric film 25 are provided on the first main surface 14a of the piezoelectric layer 14. However, the IDT electrode 11 and the dielectric film 25 may only be provided on the first main surface 14a or the second main surface 14b of the piezoelectric layer 14. Even in a case where the IDT electrode 11 and the dielectric film 25 are provided on the second main surface 14b, the frequency at which the unnecessary wave is generated can be kept away from the anti-resonant frequency as in the first example embodiment.

Acoustic wave devices according to example embodiments of the present invention can be used, for example, in a filter device. This example is described by a second example embodiment of the present invention.

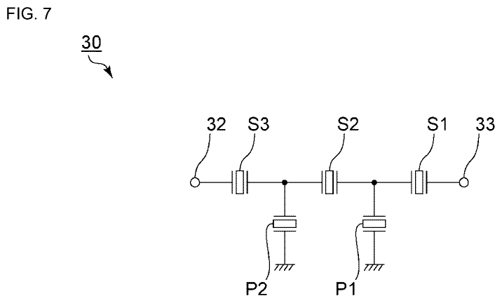

FIG. 7 is a circuit diagram of a filter device according to the second example embodiment of the present invention.

A filter device 30 is a ladder filter. The filter device 30 includes a first signal terminal 32, a second signal terminal 33, a plurality of series arm resonators, and a plurality of parallel arm resonators. In the present example embodiment, all of the series arm resonators and all of the parallel arm resonators are acoustic wave resonators, for example. All of the acoustic wave resonators are the acoustic wave devices according to the present example embodiment. However, at least one acoustic wave resonator in the filter device 30 may only be the acoustic wave device according to the present invention.

The first signal terminal 32 and the second signal terminal 33 may be configured as, for example, electrode pads, or may be configured as wirings. In the present example embodiment, the first signal terminal 32 is an antenna terminal. The antenna terminal is connected to an antenna.

The plurality of series arm resonators of the filter device 30 include a series arm resonator S1, a series arm resonator S2, and a series arm resonator S3. The plurality of parallel arm resonators include a parallel arm resonator P1 and a parallel arm resonator P2.

The series arm resonator S1, the series arm resonator S2, and the series arm resonator S3 are connected in series to each other between the first signal terminal 32 and the second signal terminal 33. The parallel arm resonator P1 is connected between a connection point between the series arm resonator S1 and the series arm resonator S2 and a ground potential. The parallel arm resonator P2 is connected between a connection point between the series arm resonator S2 and the series arm resonator S3 and the ground potential. The circuit configuration of the filter device 30 is not limited to the above-described configuration. In a case where the filter device 30 is a ladder filter, the filter device 30 may only include at least one series arm resonator and at least one parallel arm resonator.

Alternatively, the filter device 30 may include, for example, a longitudinally coupled resonator acoustic wave filter. In this case, for example, a series arm resonator or a parallel arm resonator connected to the longitudinally coupled resonator-type acoustic wave filter may be included. The series arm resonator or the parallel arm resonator may only be an acoustic wave device according to an example embodiment of the present invention.

An anti-resonant frequency of the parallel arm resonator defining a pass band of the filter device 30 is located in a pass band of the filter device 30. Therefore, the influence of the unnecessary wave generated in the vicinity of the anti-resonant frequency in the parallel arm resonator on the electrical characteristics in the pass band in the filter device 30 is particularly large. An anti-resonant frequency of the series arm resonator defining a pass band of the filter device 30 is located in the vicinity of the pass band of the filter device 30. Therefore, the influence of the unnecessary wave generated in the vicinity of the anti-resonant frequency in the series arm resonator on the electrical characteristics in the pass band in the filter device 30 is also large.

In the present example embodiment, each parallel arm resonator and each series arm resonator are acoustic wave devices according to an example embodiment of the present invention. Therefore, in each parallel arm resonator and each series arm resonator, the frequency at which the unnecessary wave is generated can be kept away from the anti-resonant frequency. As a result, it is possible to reduce or prevent the influence of the unnecessary wave on the electrical characteristics in the pass band of the filter device 30. Therefore, it is possible to reduce or present the deterioration in the filter characteristics of the filter device 30.

It is preferable that an acoustic wave device according to an example of the present invention is used as the parallel arm resonator in the ladder filter. As described above, the influence of the unnecessary wave generated in the vicinity of the anti-resonant frequency in the parallel arm resonator on the electrical characteristics in the pass band in the filter device 30 as the ladder filter is particularly large. Therefore, with the above-described configuration, it is possible to effectively reduce or prevent the deterioration in the filter characteristics of the filter device 30.

Hereinafter, the details of the thickness shear mode will be described. The “electrode” in the IDT electrode described later corresponds to an electrode finger according to an example embodiment of the present invention. The support in the following example corresponds to a support substrate according to an example embodiment of the present invention.

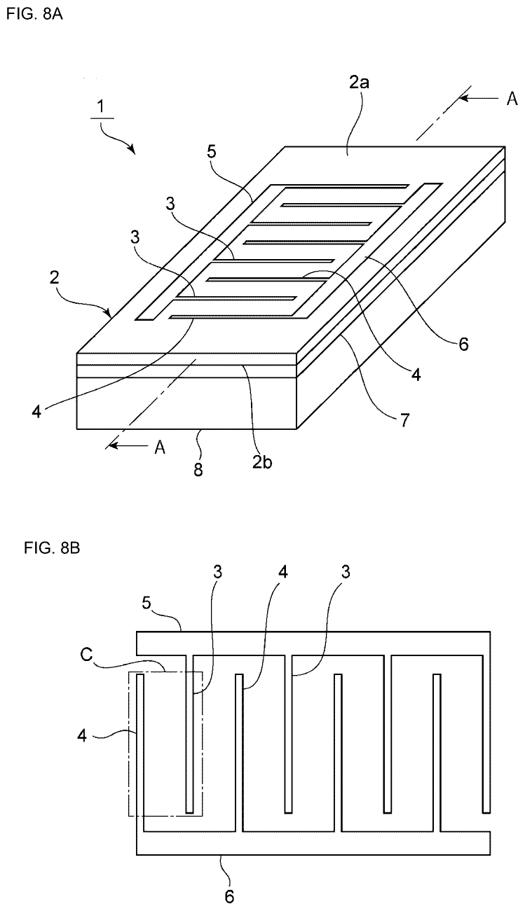

FIG. 8A is a schematic perspective view showing an appearance of the acoustic wave device using the bulk wave in the thickness shear mode, and FIG. 8B is a plan view showing the electrode structure on the piezoelectric layer, and FIG. 9 is a cross-sectional view of a portion taken along line A-A in FIG. 8A.

An acoustic wave device 1 includes a piezoelectric layer 2 made of LiNbO₃, for example. The piezoelectric layer 2 may be made of LiTaO₃, for example. A cut-angle of LiNbO₃ or LiTaO₃ is a Z cut, but may be a rotation Y cut or an X cut. The thickness of the piezoelectric layer 2 is not particularly limited, but is, for example, preferably about 40 nm or more and about 1000 nm or less, and more preferably about 50 nm or more and about 1000 nm or less in order to effectively excite the thickness shear mode. The piezoelectric layer 2 includes first and second main surfaces 2a and 2b facing each other. Electrodes 3 and 4 are provided on the first main surface 2a. Here, the electrode 3 is an example of a “first electrode” and the electrode 4 is an example of a “second electrode”. In FIGS. 8A and 8B, the plurality of electrodes 3 include a plurality of first electrode fingers connected to a first busbar 5. The plurality of electrodes 4 include a plurality of second electrode fingers connected to a second busbar 6. The plurality of electrodes 3 and the plurality of electrodes 4 are interdigitated with each other. Each of the electrodes 3 and 4 has a rectangular or substantially rectangular shape and a length direction. The electrode 3 and the electrode 4 adjacent thereto face each other in a direction orthogonal or substantially orthogonal to the length direction. Both the length direction of the electrodes 3 and 4 and the direction orthogonal or substantially orthogonal to the length direction of the electrodes 3 and 4 are directions crossing a thickness direction of the piezoelectric layer 2. Therefore, it can be said that the electrode 3 and the electrode 4 adjacent thereto face each other in the direction crossing the thickness direction of the piezoelectric layer 2. In addition, the length direction of the electrodes 3 and 4 may be changed to the direction orthogonal or substantially orthogonal to the length direction of the electrodes 3 and 4 shown in FIGS. 8A and 8B. That is, in FIGS. 8A and 8B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 8A and 8B. A plurality of pairs of structures in which the electrode 3 connected to one potential and the electrode 4 connected to the other potential are adjacent to each other are provided in a direction orthogonal or substantially orthogonal to the length direction of the electrodes 3 and 4. Here, a case where the electrodes 3 and 4 are adjacent to each other does not mean a case where the electrodes 3 and 4 are disposed to be in direct contact with each other, but mean a case where the electrodes 3 and 4 are disposed with a gap therebetween. In a case where the electrodes 3 and 4 are adjacent to each other, the electrodes connected to a hot electrode or a ground electrode, including the other electrodes 3 and 4, are not disposed between the electrodes 3 and 4. The number of pairs does not have to be integer pairs, but may be 1.5 pairs, 2.5 pairs, or the like. The center-to-center distance, that is, the pitch between the electrodes 3 and 4 is, for example, preferably in a range of about 1 μm or more and about 10 μm or less. The widths of the electrodes 3 and 4, that is, the dimensions of the electrodes 3 and 4 in the facing direction are, for example, preferably in a range of about 50 nm or more and about 1000 nm or less, and more preferably in a range of about 150 nm or more and about 1000 nm or less. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. This shall not be applied to case where a piezoelectric material with a different cut-angle is used as the piezoelectric layer 2. Here, “orthogonal” is not limited to being strictly orthogonal, but may be substantially orthogonal (angle between the direction orthogonal to the length direction of the electrodes 3 and 4 and the polarization direction is, for example, in a range of about 90°±10°).

A support 8 is laminated on the second main surface 2b side of the piezoelectric layer 2 with an insulating layer 7 interposed therebetween. The insulating layer 7 and the support 8 have a frame shape and include through holes 7a and 8a as shown in FIG. 9. As a result, a cavity portion 9 is provided. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion in which at least one pair of electrodes 3 and 4 is provided. It should be noted that the insulating layer 7 does not have to be provided. Therefore, the support 8 can be directly or indirectly laminated on the second main surface 2b of the piezoelectric layer 2.

The insulating layer 7 is made of silicon oxide, for example. However, in addition to silicon oxide, an appropriate insulating material such as, for example, silicon oxynitride or alumina can be used. The support 8 is made of Si, for example. A plane orientation of the plane of Si on the piezoelectric layer 2 side may be (100), (110), or (111). Si of the support 8 is preferably high resistance having a resistivity of, for example, about 4 kΩcm or more. However, the support 8 can also be made of an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metals or alloys such as, for example, Al and AlCu alloys. In the acoustic wave device 1, the electrodes 3 and 4 and the first and second busbars 5 and 6 have a structure including, for example, an Al film is laminated on a Ti film. A close contact layer other than the Ti film may be used.

During driving, the AC voltage is applied between the plurality of electrodes 3 and the plurality of electrodes 4. More specifically, the AC voltage is applied between the first busbar 5 and the second busbar 6. As a result, it is possible to obtain the resonance characteristics using the bulk wave in the thickness shear mode excited in the piezoelectric layer 2. In the acoustic wave device 1, in a case where d is the thickness of the piezoelectric layer 2 and p is the center-to-center distance between any adjacent electrodes 3 and 4 among the plurality of pairs of electrodes 3 and 4, d/p is, for example, about 0.5 or less. As a result, the bulk wave in the thickness shear mode is effectively excited, and good resonance characteristics can be obtained. More preferably, d/p is, for example, about 0.24 or less, and in this case, better resonance characteristics can be obtained.

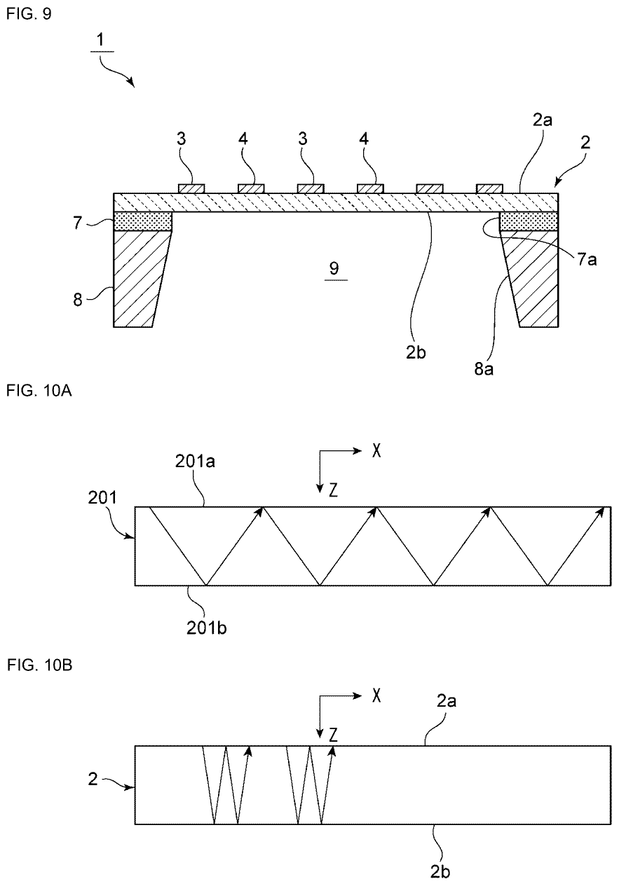

In the acoustic wave device 1, since the above-described configuration is provided, even in a case where the number of pairs of the electrodes 3 and 4 is reduced in order to reduce the size, the Q value is unlikely to be decreased. This is because the propagation loss is small even in a case where the number of electrode fingers in the reflectors on both sides is small. In addition, the number of electrode fingers can be reduced by using the bulk wave in the thickness shear mode. A difference between the Lamb wave used in the acoustic wave device and the bulk wave in the thickness shear mode will be described with reference to FIGS. 10A and 10B.

FIG. 10A is a schematic elevational cross-sectional view showing the Lamb wave that propagates through the piezoelectric film of the acoustic wave device as disclosed in Japanese Unexamined Patent Application Publication No. 2012-257019. Here, the wave propagates in a piezoelectric film 201 as indicated by an arrow. Here, in the piezoelectric film 201, a first main surface 201a and a second main surface 201b face each other, and a thickness direction connecting the first main surface 201a and the second main surface 201b is a Z direction. An X direction is a direction in which the electrode fingers of the IDT electrodes are arranged. As shown in FIG. 10A, in the Lamb wave, the wave propagates in the X direction as shown in the figure. Since the wave is a plate wave, although the piezoelectric film 201 vibrates as a whole, since the wave propagates in the X direction, the reflectors are disposed on both sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as shown in FIG. 10B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X-direction component of the wave is significantly smaller than a Z-direction component. In addition, since the resonance characteristics are obtained by the propagation of the wave in the Z direction, the propagation loss is unlikely to occur even when the number of the electrode fingers of the reflector is reduced. Further, even in a case where the number of pairs of the electrode pair including the electrodes 3 and 4 is reduced when the size reduction is attempted, the Q value is unlikely to be decreased.

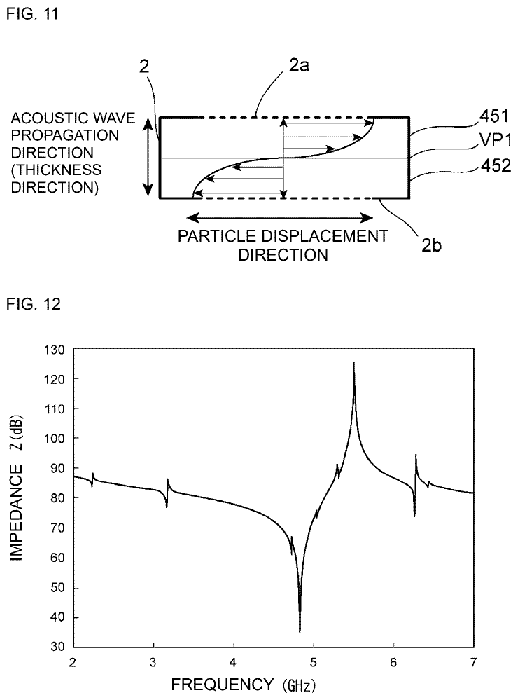

Amplitude directions of the bulk waves of the thickness shear mode are opposite to each other between a first region 451 included in the excitation region C of the piezoelectric layer 2 and a second region 452 included in the excitation region C, as shown in FIG. 11. FIG. 11 schematically shows the bulk waves when the voltage is applied between the electrodes 3 and 4 so that the potential of the electrode 4 is higher than the potential of the electrode 3. The first region 451 is a region of the excitation region C between a virtual plane VP1, which is orthogonal or substantially orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 is provided, the waves are not propagated in the X direction, and thus the number of pairs of the electrode pair including the electrodes 3 and 4 does not have to be plural. That is, at least one pair of electrodes may only be provided.

For example, the electrode 3 is an electrode connected to a hot potential and the electrode 4 is an electrode connected to a ground potential. However, the electrode 3 may be connected to the ground potential and the electrode 4 may be connected to the hot potential. In the acoustic wave device 1, at least one pair of electrodes is the electrodes connected to the hot potential or the electrodes connected to the ground potential, as described above, and no floating electrodes are provided.

FIG. 12 is a view showing the resonance characteristics of the acoustic wave device shown in FIG. 9. It should be noted that the design parameters of the acoustic wave device 1 with the resonance characteristics are as follows.

Piezoelectric layer 2: LiNbO₃ with Euler angles (0°, 0°, 90°), thickness=about 400 nm.

When viewed in the direction orthogonal or substantially orthogonal to the length direction of the electrodes 3 and 4, the length of the region in which the electrodes 3 and 4 overlap each other, that is, the length of the excitation region C=about 40 μm, the number of pairs of the electrodes including the electrodes 3 and 4=21 pairs, the distance between the centers of the electrodes =about 3 μm, the width of the electrodes 3 and 4 =about 500 nm, and d/p=about 0.133.

Insulating layer 7: silicon oxide film having a thickness of about 1 μm.

### Support 8: Si.

The length of the excitation region C is the dimension along the length direction of the electrodes 3 and 4 of the excitation region C.

In the acoustic wave device 1, an electrode-to-electrode distance of the electrode pair including the electrodes 3 and 4 is made equal or substantially equal in all of the plurality of pairs. That is, the electrodes 3 and 4 are disposed at equal or substantially equal pitches.

As is clear from FIG. 12, good resonance characteristics with the fractional bandwidth of about 12.5% are obtained regardless of the presence of the reflector.

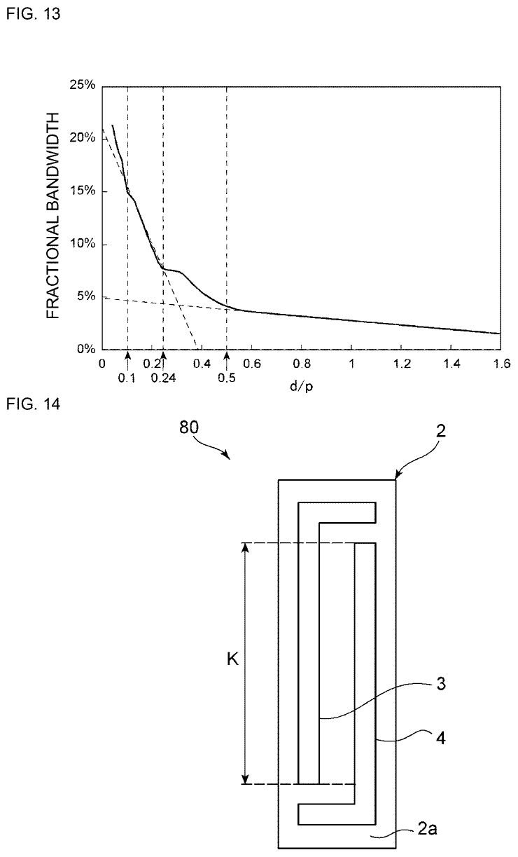

In a case where the thickness of the piezoelectric layer 2 is d and the center-to-center distance of the electrodes 3 and 4 is p, in the acoustic wave device 1, as described above, for example, d/p is about 0.5 or less, and more preferably about 0.24 or less. The description thereof will be made with reference to FIG. 13.

A plurality of acoustic wave devices are obtained by changing d/p in the same manner as the acoustic wave device that obtains the resonance characteristics shown in FIG. 12. FIG. 13 is a view showing a relationship between d/p and the fractional bandwidth as the resonator of the acoustic wave device.

As is clear from FIG. 13, when d/p >about 0.5, the fractional bandwidth is less than about 5% even in a case where d/p is adjusted. On the other hand, in a case where d/p≤about 0.5, when d/p is changed within this range, the fractional bandwidth of about 5% or more can be obtained, that is, the resonator having a high coupling coefficient can be formed. In addition, in a case where d/p is about 0.24 or less, the fractional bandwidth can be increased to about 7% or more. In addition, by adjusting d/p within this range, a resonator with a wider fractional bandwidth can be obtained, and a resonator with a higher coupling coefficient can be realized. Therefore, it can be seen that, by adjusting d/p to about 0.5 or less, it is possible to configure a resonator having a high coupling coefficient using the bulk wave in the thickness shear mode.

FIG. 14 is a plan view of the acoustic wave device using the bulk wave in the thickness shear mode. In an acoustic wave device 80, the one pair of electrodes including the electrode 3 and electrode 4 is provided on the first main surface 2a of the piezoelectric layer 2. K in FIG. 14 is a cross width. As described above, in acoustic wave devices according to example embodiments of the present invention, the number of pairs of the electrodes may be one pair. Even in this case, when d/p is about 0.5 or less, it is possible to effectively excite the bulk wave in the thickness shear mode.

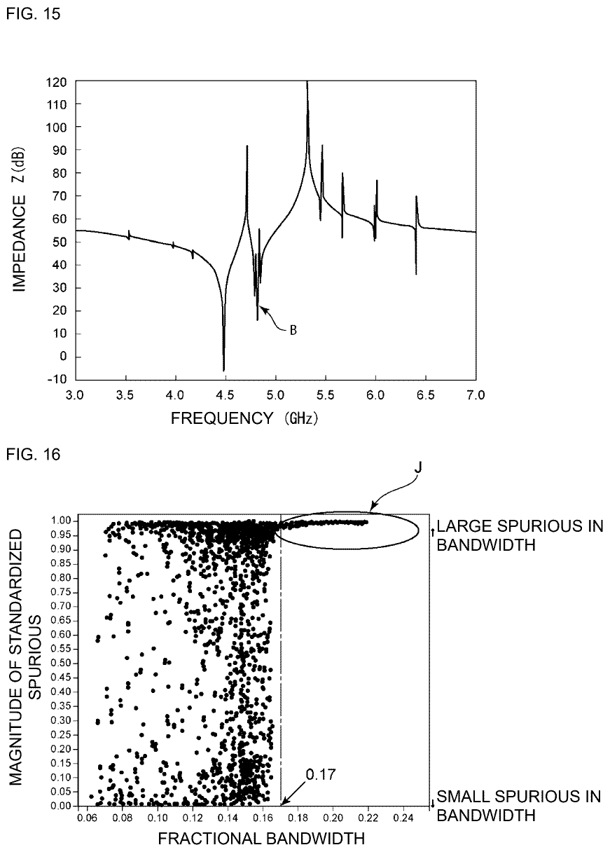

In the acoustic wave device 1, preferably, the metallization ratio MR of any adjacent electrodes 3 and 4 among the plurality of electrodes 3 and 4 to the excitation region C, which is the region in which the adjacent electrodes 3 and 4 overlap each other when viewed in the facing direction, satisfies MR≤about 1.75(d/p)+0.075, for example. In this case, the spurious response can be effectively reduced. The description thereof will be made with reference to FIGS. 15 and 16. FIG. 15 is a reference view showing an example of the resonance characteristics of the acoustic wave device 1. The spurious response indicated by an arrow B appears between the resonant frequency and the anti-resonant frequency. d/p=about 0.08 and the Euler angles of LiNbO₃ are (0°, 0°, 90°). Also, the metallization ratio MR is about 0.35.

The metallization ratio MR will be described with reference to FIG. 8B. In the electrode structure of FIG. 8B, it is assumed that, when focusing on the one pair of electrodes 3 and 4, only the one pair of electrodes 3 and 4 is provided. In this case, a portion surrounded by a one-dot chain line is the excitation region C. The excitation region C is a region of the electrode 3 that overlaps the electrode 4 when the electrode 3 and the electrode 4 are viewed in the direction orthogonal or substantially orthogonal to the length direction of the electrodes 3 and 4, that is, in the facing direction, a region of the electrode 4 that overlaps the electrode 3, and a region in which the electrode 3 and the electrode 4 overlap each other in the region between the electrode 3 and the electrode 4. An area of the electrodes 3 and 4 in the excitation region C with respect to an area of this excitation region C is the metallization ratio MR. That is, the metallization ratio MR is a ratio of an area of the metallization portion to the area of the excitation region C.

In a case where the plurality of pairs of electrodes are provided, a ratio of the metallization portion included in the entire excitation region to a total area of the excitation region need only be MR.

FIG. 16 is a view showing a relationship between a fractional bandwidth and a phase rotation amount of an impedance of the spurious response standardized at about 180 degrees as a magnitude of the spurious response in a case where a large number of acoustic wave resonators are configured according to the example embodiment of the acoustic wave device 1. The fractional bandwidth is adjusted by changing the film thickness of the piezoelectric layer and the dimensions of the electrodes. Moreover, FIG. 16 shows the results in a case where the piezoelectric layer made of the Z-cut LiNbO₃ is used, but the same tendency is obtained in a case where piezoelectric layers with other cut-angles are used.

In a region surrounded by an ellipse J in FIG. 16, the spurious response is as large as about 1.0. As is clear from FIG. 16, in a case where the fractional bandwidth exceeds about 0.17, that is, exceeds about 17%, a large spurious response with a spurious level of about 1 or more appears in a pass band even when the parameters defining the fractional bandwidth are changed. That is, as in the resonance characteristics shown in FIG. 15, a large spurious response indicated by an arrow B appears within the band. Therefore, the fractional bandwidth is preferably about 17% or less, for example. In this case, by adjusting the film thickness of the piezoelectric layer 2 and the dimensions of the electrodes 3 and 4, the spurious response can be reduced.

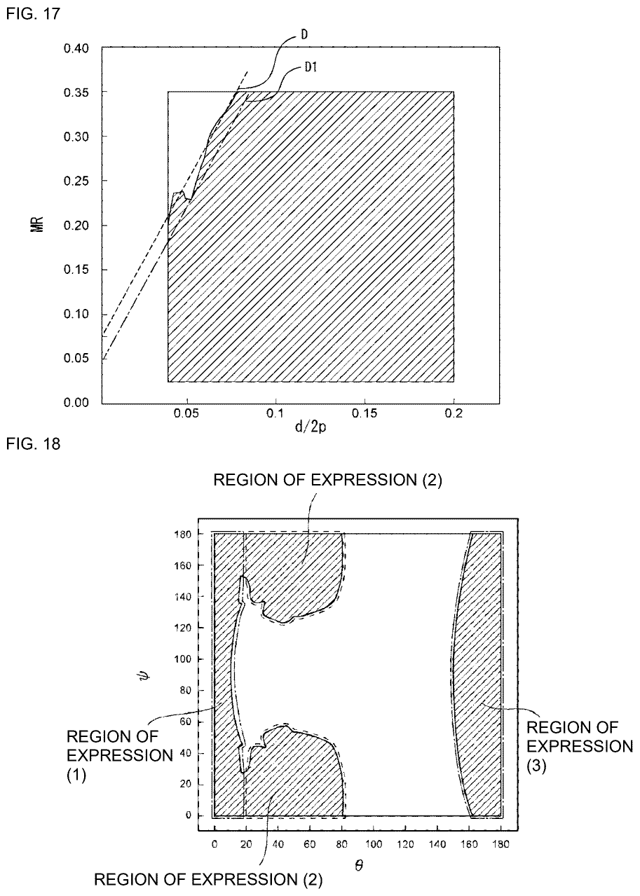

FIG. 17 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 17 is a region in which the fractional bandwidth is about 17% or less. A boundary between the hatched region and a non-hatched region is expressed by MR=about 3.5(d/2p)+0.075. That is, MR=about 1.75(d/p)+0.075. Therefore, preferably, MR ≤about 1.75(d/p) +0.075, for example. In this case, it is easy to set the fractional bandwidth to about 17% or less. More preferably, for example, it is a region on a right side of MR=about 3.5(d/2p)+0.05 indicated by a one-dot chain line D1 in FIG. 17. That is, in a case where MR≤about 1.75(d/p)+0.05, the fractional bandwidth can be reliably set to about 17% or less.

FIG. 18 is a view showing a map of the fractional bandwidth with respect to Euler angles (0°, θ, ψ) of LiNbO₃ in a case where d/p is infinitely close to 0. A hatched portion in FIG. 18 is a region in which the fractional bandwidth of at least 5% or more is obtained, and in a case where a range of the region is approximated, the range is a range represented by Expressions (1), (2), and (3).

(0°±10°, 0° to 20°, any ψ) Expression (1)

(0°±10°, 20° to 80°, 0° to 60° (1−(θ−50)²/900)^{1/2})

or (0°±10°, 20° to 80°, [180°−60° (1−(θ−50)²/900)^{1/2}] to 180°) Expression (2)

(0°±10°, [180°−30°(1−(ψ−90)²/8100)^{1/2}] to 180°, any ψ) Expression (3)

Therefore, in a case of the Euler angle range of Expression (1), Expression (2), or Expression (3), the fractional bandwidth can be sufficiently widened, which is preferable. The same applies to a case where the piezoelectric layer 2 is the lithium tantalate layer.

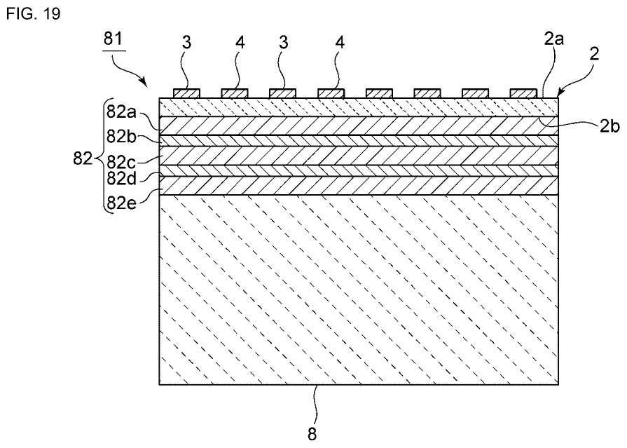

FIG. 19 is an elevational cross-sectional view of an acoustic wave device according to an example embodiment of the present invention including an acoustic multilayer film.

In an acoustic wave device 81, an acoustic multilayer film 82 is laminated on the second main surface 2b of the piezoelectric layer 2. The acoustic multilayer film 82 has a laminated structure including low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without including the cavity portion 9 of the acoustic wave device 1. Also in the acoustic wave device 81, the resonance characteristics based on the bulk wave in the thickness shear mode can be obtained by adjusting d/p to, for example, about 0.5 or less. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may only be provided on a side farther from the piezoelectric layer 2 than the low acoustic impedance layers 82a, 82c, and 82e.

The low acoustic impedance layers 82a, 82c, and 82e and the high acoustic impedance layers 82b and 82d can be made of an appropriate material as long as the above-described relationship of the acoustic impedance is satisfied. Examples of the materials of the low acoustic impedance layers 82a, 82c, and 82e include silicon oxide and silicon oxynitride. In addition, examples of the materials of the high acoustic impedance layers 82b and 82d include alumina, silicon nitride, and metal.

In the acoustic wave device according to the first example embodiment, for example, the acoustic multilayer film 82 shown in FIG. 19 may be provided as the acoustic reflection film between the support and the piezoelectric layer. Specifically, the support and the piezoelectric layer may be disposed such that at least a portion of the support and at least a portion of the piezoelectric layer face each other with the acoustic multilayer film 82 interposed therebetween. In this case, in the acoustic multilayer film 82, the low acoustic impedance layer and the high acoustic impedance layer need only be alternately laminated. The acoustic multilayer film 82 may be the acoustic reflection portion in the acoustic wave device.

In the acoustic wave device according to the first example embodiment that uses the bulk wave in the thickness shear mode, as described above, d/p is, for example, preferably about 0.5 or less, and more preferably about 0.24 or less. As a result, better resonance characteristics can be obtained. Further, in the excitation region in the acoustic wave device according to the first example embodiment that uses the bulk wave in the thickness shear mode, as described above, for example, preferably, MR≤about 1.75 (d/p)+0.075 is satisfied. In this case, it is possible to more reliably reduce or prevent the spurious response.

The functional electrode in the acoustic wave device according to the first example embodiment that uses the bulk wave in the thickness shear mode may be the functional electrode having the one pair of electrodes shown in FIG. 14.

It is preferable that the piezoelectric layer in the acoustic wave device according to the first example embodiment that uses the bulk wave in the thickness shear mode is the lithium niobate layer or the lithium tantalate layer, for example. In addition, it is preferable that the Euler angles (φ, θ, ψ) of lithium niobate or lithium tantalate of the piezoelectric layer are in the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a support including a support substrate, and a piezoelectric layer on the support and made of lithium tantalate or lithium niobate;
a functional electrode on the piezoelectric layer and including at least one pair of electrode fingers; and
a dielectric film on the piezoelectric layer and covering the at least one pair of electrode fingers; wherein
an acoustic reflection portion is provided at a position overlapping at least a portion of the functional electrode in plan view;
where a thickness of the piezoelectric layer is d and a center-to-center distance between the electrode fingers adjacent to each other is p, d/p is about 0.5 or less;
each of the electrode fingers includes a first surface and a second surface facing each other in a thickness direction, and a side surface connected to the first surface and the second surface, the second surface being located on a side of the piezoelectric layer;
the dielectric film includes an electrode finger surface cover portion covering the first surface of the electrode finger, a side surface cover portion that covering the side surface of the electrode finger, and a piezoelectric layer cover portion covering the piezoelectric layer;
the electrode finger surface cover portion includes a center portion located at a center in a direction orthogonal or substantially orthogonal to a direction in which the electrode fingers extend;
where a portion in which the side surface cover portion and the piezoelectric layer cover portion are connected to each other is a connection portion, and a minimum value of a thickness of the connection portion is tcm, tcm≥0; and
where a thickness of the center portion of the electrode finger surface cover portion is te, te>tcm.

2. The acoustic wave device according to claim 1, wherein
the side surface cover portion of the dielectric film includes a first side surface cover portion and a second side surface cover portion that face each other in the direction orthogonal or substantially orthogonal to the direction in which the electrode finger extends; and
where the connection portion, defining a portion in which the first side surface cover portion and the piezoelectric layer cover portion are connected to each other, is a first connection portion, the connection portion, which is a portion in which the second side surface cover portion and the piezoelectric layer cover portion are connected to each other, is a second connection portion, a thickness of the first connection portion is tc1, and a thickness of the second connection portion is tc2, te>tc1 and te>tc2.

3. The acoustic wave device according to claim 1, wherein the functional electrode is an interdigital transducer electrode including a plurality of pairs of the electrode fingers.

4. The acoustic wave device according to claim 1, wherein d/p is about 0.24 or less.

5. The acoustic wave device according to claim 1, wherein a region in which adjacent ones of electrode fingers overlap each other when seen from a direction in which the adjacent electrode fingers face each other is an excitation region, and where a metallization ratio of the at least one pair of electrode fingers to the excitation region is MR, MR≤about 1.75(d/p)+0.075 is satisfied.

6. The acoustic wave device according to claim 1, wherein
Euler angles (φ, θ, ψ) of the lithium niobate or the lithium tantalate of the piezoelectric layer are in a range of Expression (1), Expression (2), or Expression (3):
(0°±10°, 0° to 20°, any ψ) Expression (1)
(0°±10°, 20° to 80°, 0° to 60° (1−(θ−50)²/900)^{1/2})
or (0°±10°, 20° to 80°, [180°−60° (1−(θ−50)²/900)^{1/2}] to 180°) Expression (2)
(0°±10°, [180°−30°(1−(ψ−90)²/8100)^{1/2}] to 180°, any ψ) Expression (3)

7. The acoustic wave device according to claim 1, wherein the acoustic reflection portion is a cavity portion, and the support and the piezoelectric layer are positioned such that a portion of the support and a portion of the piezoelectric layer face each other with the cavity portion interposed between the support and the piezoelectric layer.

8. The acoustic wave device according to claim 1, wherein
the acoustic reflection portion includes an acoustic reflection film including a high acoustic impedance layer having a relatively high acoustic impedance and a low acoustic impedance layer having a relatively low acoustic impedance; and
the support and the piezoelectric layer are positioned such that at least a portion of the support and at least a portion of the piezoelectric layer face each other with the acoustic reflection film interposed between the support and the piezoelectric layer.

9. The acoustic wave device according to claim 1, wherein a center-to-center distance between the electrodes of the at least one pair of electrodes is in a range of about 1 μm or more and about 10 μm or less.

10. The acoustic wave device according to claim 1, wherein a width of each of the electrodes of the at least one pair of electrodes is in a range of about 50 nm or more and about 1000 nm or less.

11. A ladder filter comprising:
at least one series arm resonator; and
at least one parallel arm resonator; wherein
the at least one parallel arm resonator is defined by the acoustic wave device according to claim 1.

12. The ladder filter according to claim 11, wherein
the side surface cover portion of the dielectric film includes a first side surface cover portion and a second side surface cover portion that face each other in the direction orthogonal or substantially orthogonal to the direction in which the electrode finger extends; and
where the connection portion, defining a portion in which the first side surface cover portion and the piezoelectric layer cover portion are connected to each other, is a first connection portion, the connection portion, which is a portion in which the second side surface cover portion and the piezoelectric layer cover portion are connected to each other, is a second connection portion, a thickness of the first connection portion is tc1, and a thickness of the second connection portion is tc2, te>tc1 and te>tc2.

13. The ladder filter according to claim 11, wherein the functional electrode is an interdigital transducer electrode including a plurality of pairs of the electrode fingers.

14. The ladder filter according to claim 11, wherein d/p is about 0.24 or less.

15. The ladder filter according to claim 11, wherein a region in which adjacent ones of electrode fingers overlap each other when seen from a direction in which the adjacent electrode fingers face each other is an excitation region, and where a metallization ratio of the at least one pair of electrode fingers to the excitation region is MR, MR≤about 1.75(d/p)+0.075 is satisfied.

16. The ladder filter according to claim 11, wherein
Euler angles (φ, θ, ψ) of the lithium niobate or the lithium tantalate of the piezoelectric layer are in a range of Expression (1), Expression (2), or Expression (3):
(0°±10°, 0° to 20°, any ψ) Expression (1)
(0°±10°, 20° to 80°, 0° to 60° (1−(θ−50)²/900)^{1/2})
or (0°±10°, 20° to 80°, [180°−60° (1−(θ−50)²/900)^{1/2}] to 180°) Expression (2)
(0°±10°, [180°−30°(1−(ψ−90)²/8100)^{1/2}] to 180°, any ψ) Expression (3)

17. The ladder filter according to claim 11, wherein the acoustic reflection portion is a cavity portion, and the support and the piezoelectric layer are positioned such that a portion of the support and a portion of the piezoelectric layer face each other with the cavity portion interposed between the support and the piezoelectric layer.

18. The ladder filter according to claim 11, wherein
the acoustic reflection portion includes an acoustic reflection film including a high acoustic impedance layer having a relatively high acoustic impedance and a low acoustic impedance layer having a relatively low acoustic impedance; and
the support and the piezoelectric layer are positioned such that at least a portion of the support and at least a portion of the piezoelectric layer face each other with the acoustic reflection film interposed between the support and the piezoelectric layer.

19. The ladder filter according to claim 11, wherein a center-to-center distance between the electrodes of the at least one pair of electrodes is in a range of about 1 μm or more and about 10 μm or less.

20. The ladder filter according to claim 11, wherein a width of each of the electrodes of the at least one pair of electrodes is in a range of about 50 nm or more and about 1000 nm or less.
